(19) United States
(12) Patent Application Publication
(10) Pub. No.: US 2015/0200289 A1
(43) Pub. Date: Jul. 16, 2015

(54) TUNNELING FIELD EFFECT TRANSISTOR

(71) Applicant: Samsung Electronics Co., Ltd., Suwon-si (KR)

(72) Inventors: Xin-Gui ZHANG, Suwon-si (KR); Tae-Yong KWON, Suwon-si (KR); Jung-Gil YANG, Suwon-si (KR); Sang-Su KIM, Yongin-si (KR)

(21) Appl. No.: 14/570,331

(22) Filed: Dec. 15, 2014

(30) Foreign Application Priority Data
Jan. 16, 2014 (KR) 10-2014-0005597

(51) Int. Cl. H01L 29/78; H01L 29/205; H01L 29/165

(52) U.S. Cl. CPC H01L 29/78; H01L 29/165; H01L 29/205

(57) ABSTRACT

The inventive concepts provide tunneling field effect transistors. The tunneling field effect transistor includes a source region, a drain region, a channel region, and a pocket region. The channel region includes a first material, and is disposed between the source region and the drain region. The pocket region includes a second material, and is disposed between the source region and the drain region. The channel region includes a first region adjacent to the source region, and a second region adjacent to the drain region. A first energy band gap of the first region is smaller than a second energy band gap of the second region, and a third energy band gap of the pocket region is different from the first energy band gap and the second energy band gap.

### CROSS-REFERENCE TO RELATED APPLICATION

This U.S. non-provisional patent application claims priority under 35 U.S.C. §119 to Korean Patent Application No. 10-2014-0005597, filed on Jan. 16, 2014, in the Korean Intellectual Property Office, the disclosure of which is hereby incorporated by reference in its entirety.

### BACKGROUND

The inventive concepts relate to semiconductor devices and, more particularly, to tunneling field effect transistors.

Semiconductor devices are widely used in the electronics industry because of their small size, multi-function, and/or low manufacture costs. Semiconductor devices may be categorized as any one of semiconductor memory devices storing logical data, semiconductor logic devices processing logical data, and hybrid semiconductor devices having both the function of the semiconductor memory devices and the function of the semiconductor logic devices. Semiconductor devices having excellent characteristics have been increasingly demanded with the development of the electronics industry. For example, high-reliable, high-speed and/or multi-functional semiconductor devices have been increasingly demanded. To satisfy these demands, structures of semiconductor devices have been complicated and semiconductor devices have been highly integrated.

### SUMMARY

Embodiments of the inventive concepts may provide tunneling field effect transistors having a high on-current and a low off-current.

In one aspect of the inventive concept, a tunneling field effect transistor may include: a source region, a drain region, and a channel region including a first material, and disposed between the source region and the drain region; and a pocket region including a second material different from the first material, and disposed between the source region and the drain region. The channel region may include a first region adjacent to the source region, and a second region adjacent to the drain region. A first energy band gap of the first region may be smaller than a second energy band gap of the second region, and a third energy band gap of the pocket region may be different from the first energy band gap and the second energy band gap.

In some embodiments, the pocket region may be formed between the source region and the channel region, and the third energy band gap may be smaller than the first energy band gap.

In some embodiments, the first material may include indium-gallium-arsenic (InGaAs), and the second material may include indium-arsenic (InAs).

In some embodiments, a gallium (Ga) concentration of the first region may be lower than a gallium concentration of the second region.

In some embodiments, the first material may include indium-gallium-antimony (InGaSb), and the second material may include indium-antimony (InSb).

In some embodiments, an indium (In) concentration of the first region may be greater than an indium concentration of the second region.

In some embodiments, the pocket region may be formed between the drain region and the channel region, and the third energy band gap may be greater than the second energy band gap.

In some embodiments, the first material may include indium-gallium-arsenic (InGaAs), and the second material may include at least one of indium-phosphorus (InP) and indium-aluminum-arsenic (InAlAs).

In some embodiments, the first material may include indium-gallium-antimony (InGaSb), and the second material may include indium-aluminum-antimony (InAlSb).

In some embodiments, an energy band gap of the channel region may become gradually smaller from the second region to the first region.

In some embodiments, an energy band gap of the channel region may become smaller stepwise from the second region to the first region.

In some embodiments, the source region, the drain region, and the channel region may be provided on a substrate, and the source region and the drain region may be spaced apart from each other in a direction substantially perpendicular to a top surface of the substrate.

In some embodiments, the tunneling field effect transistor may further include: a gate dielectric layer and a gate electrode stacked on each other on a sidewall of the channel region.

In some embodiments, the tunneling field effect transistor may further include: a device isolation layer disposed at both sides of the channel region when viewed from a plan view. The gate dielectric layer and the gate electrode may be in contact with a top surface of the device isolation layer.

In some embodiments, the pocket region may include: a first pocket region between the source region and the channel region; and a second pocket region between the drain region and the channel region. An energy band gap of the first pocket region may be smaller than the energy band gap of the first region, and an energy band gap of the second pocket region may be greater than the energy band gap of the second region.

In another aspect of the inventive concept, a tunneling field effect transistor may include: a source region, a drain region, and a channel region between the source region and the drain region; and a first pocket region between the source region and the channel region. The channel region may include: a first region adjacent to the source region; and a second region adjacent to the drain region. An energy band gap of the first region may be smaller than an energy band gap of the second region, and an energy band gap of the first pocket region may be smaller than the energy band gap of the first region.

In some embodiments, the channel region may include indium-gallium-arsenic (InGaAs), and the first pocket region may include indium-arsenic (InAs). A gallium (Ga) concentration of the first region may be lower than a gallium concentration of the second region.

In some embodiments, the channel region may include indium-gallium-antimony (InGaSb), and the first pocket region includes indium-antimony (InSb). An indium (In) concentration of the first region may be greater than an indium concentration of the second region.

In some embodiments, the tunneling field effect transistor may further include: a second pocket region between the drain region and the channel region. An energy band gap of the second pocket region may be greater than the energy band gap of the second region.

In some embodiments, the source region, the drain region, and the channel region may be provided on a substrate, and the source region and the drain region may be spaced apart from each other in a direction substantially perpendicular to a top surface of the substrate.

In still another aspect of the inventive concept, a semiconductor device may include a substrate and one or more tunneling field effect transistors. At least one of the one or more tunneling field effect transistors may include: a source structure and a drain structure on the substrate; a channel layer including a first compound including a first intrinsic material, and disposed between the source structure and the drain structure; and a first layer including a second compound including a second intrinsic material different from the first intrinsic material, and disposed between the source structure and the drain structure. A concentration of one element of the first compound may vary in a direction from the source region to the drain region.

In further still another aspect of the inventive concept, a semiconductor device may include one or more tunneling field effect transistors. At least a first tunneling field effect transistor may include: a substrate; a source structure and a drain structure on the substrate; a channel layer including a first area adjacent to the source structure, and a second area adjacent to the drain structure, the channel layer formed between the source structure and the drain structure; a first layer contacting a first surface of the channel layer; a gate electrode; and a gate dielectric layer including a first surface contacting the gate electrode, and a second surface contacting the channel layer. The channel layer may include a first compound and the first layer includes a second compound different from the first compound. A thickness of the channel layer is greater than a thickness of the first layer.

### BRIEF DESCRIPTION OF THE DRAWINGS

The inventive concepts will become more apparent in view of the attached drawings and accompanying detailed description.

FIG. 1 is a cross-sectional view illustrating a tunneling field effect transistor according to some example embodiments of the inventive concepts;

FIG. 2 is an energy band diagram when the tunneling field effect transistor of FIG. 1 is an N-type tunneling field effect transistor according to one example embodiment;

FIGS. 3 to 7 are cross-sectional views illustrating a method of manufacturing a tunneling field effect transistor according to some example embodiments of the inventive concepts;

FIG. 8 is a cross-sectional view illustrating a tunneling field effect transistor according to other example embodiments of the inventive concepts;

FIG. 9 is an energy band diagram of the tunneling field effect transistor of FIG. 8 according to one example embodiment;

FIG. 10 is a cross-sectional view illustrating a tunneling field effect transistor according to still other example embodiments of the inventive concepts;

FIG. 11 is an energy band diagram of the tunneling field effect transistor of FIG. 10 according to one example embodiment;

FIG. 12 is a cross-sectional view illustrating a tunneling field effect transistor according to yet other example embodiments of the inventive concepts;

FIGS. 13A, 13B, and 13C are energy band diagrams of a general N-channel tunneling field effect transistor;

FIG. 14 is a schematic block diagram illustrating an electronic system including a semiconductor device according to certain embodiments of the inventive concepts; and

FIG. 15 illustrates an example of a mobile phone applied with the electronic system of FIG. 14.

### DETAILED DESCRIPTION OF THE EMBODIMENTS

The present disclosure will now be described more fully hereinafter with reference to the accompanying drawings, in which exemplary embodiments of the inventive concepts are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concepts. In the drawings, embodiments of the inventive concepts are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. Expressions such as “at least one of,” when preceding a list of elements, modify the entire list of elements and do not modify the individual elements of the list. As used herein, the term “and/or” includes any and all combinations of one or more of the associated listed items. It will be understood that when an element is referred to as being “connected” or “coupled” to another element, it may be directly connected or coupled to the other element or intervening elements may be present. The term “contact,” as used herein, refers to a direct contact, unless indicated otherwise.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless the context indicates otherwise, terms such as “same,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning.

Additionally, the embodiments in the detailed description will be described with sectional views as ideal exemplary views of the inventive concepts. Accordingly, shapes of the exemplary views may be modified according to manufacturing techniques and/or allowable errors. Therefore, the embodiments of the inventive concepts are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. Unless indicated otherwise, these terms are only used to distinguish one element from another element. Thus, a first element in some embodiments could be termed a second element in other embodiments without departing from the teachings of the present invention. Exemplary embodiments of aspects of the present inventive concepts explained and illustrated herein include their complementary counterparts. The same reference numerals or the same reference designators denote the same or similar elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

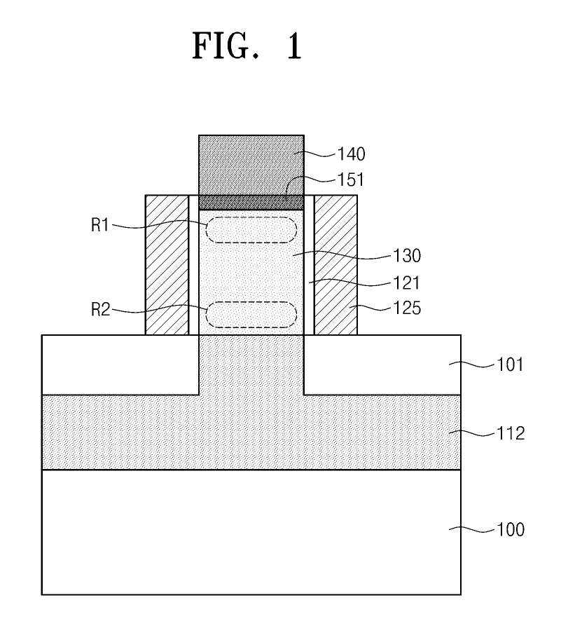

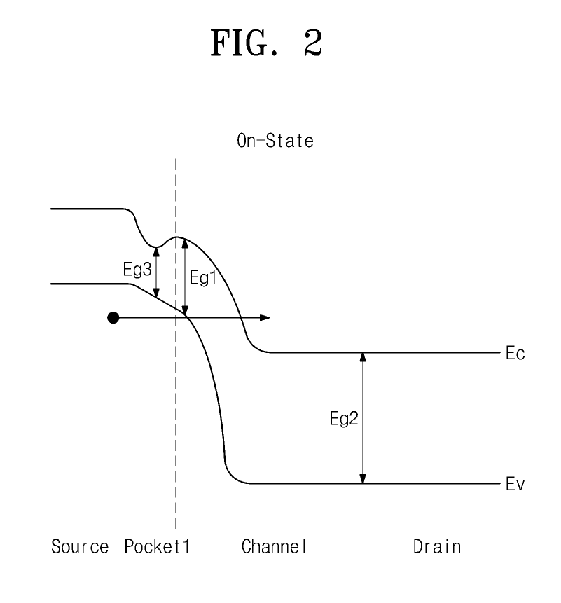

FIG. 1 is a cross-sectional view illustrating a tunneling field effect transistor according to some example embodiments of the inventive concepts. FIG. 2 is an energy band diagram when the tunneling field effect transistor of FIG. 1 is an N-type tunneling field effect transistor.

Referring to FIG. 1, a tunneling field effect transistor according to the present embodiment may include a drain region 112, a channel region 130 and a source region 140 which are sequentially stacked on a substrate 100. The term “drain region,” “channel region,” and “source region,” as used herein, refers to a “drain,” “channel,” and “source.” For example, a drain region 112 may function as a drain, a channel region 130 may function as a channel, and a source region 140 may function as a source. The drain region 112 and the source region 140 may be spaced apart from each other in a direction substantially perpendicular to a top surface of the substrate 100. The channel region 130 may include a first region R1 adjacent to the source region 140 and a second region R2 adjacent to the drain region 112. The substrate 100 may be, for example, a silicon substrate or a substrate including silicon. The drain region 112 may include a protrusion extending upward from the substrate 100 and a recess region disposed at both sides of the protrusion. A device isolation layer 101 may be provided in the recess region. The device isolation layer 101 may include, for example, a silicon oxide layer. In one embodiment, a tunneling field effect transistor may be included in a semiconductor device.

A first pocket region 151 may be provided between the drain region 112 and the source region 140. In some embodiments, the first pocket region 151 may be disposed between the source region 140 and the channel region 130.

In one embodiment, a thickness of the first pocket region 151 is less than a thickness of the channel region 130. Each thickness of the first pocket region 151 and the channel region 130 may be in a direction between the substrate 100 and the source region 140.

In one embodiment, the first pocket region 151 may be an intrinsic region (e.g., including only the intrinsic material without any dopant). In another embodiment, the first pocket region 151 may be a doped region (e.g., including the intrinsic material and dopant).

A gate dielectric layer 121 and a gate electrode 125 may be sequentially provided on a sidewall of the channel region 130. Bottom surfaces of the gate dielectric layer 121 and the gate electrode 125 may be in contact with the device isolation layer 101. The gate dielectric layer 121 may include a high-k dielectric material having a dielectric constant higher than that of a silicon oxide layer. For example, the gate dielectric layer 121 may include HfO₂, ZrO₂, or Ta₂O₅. The gate electrode 125 may include, for example, a conductive metal nitride (e.g., TiN, TaN, or WN) and/or a metal (e.g., Ti, Ta, or W).

A conductivity type of the drain region 112 may be different from a conductivity type of the source region 140. In some embodiments, if the tunneling field effect transistor is an N-type tunneling field effect transistor, the drain region 112 may be an N-type dopant region and the source region 140 may be a P-type dopant region. In other embodiments, if the tunneling field effect transistor is a P-type tunneling field effect transistor, the drain region 112 may be a P-type dopant region and the source region 140 may be an N-type dopant region. For example, the channel region 130 may be an intrinsic region (e.g., including only the intrinsic material without any dopant). Alternatively, the channel region 130 may be a P-type or N-type dopant region (e.g., including the intrinsic material and dopant) that is more lightly doped than the drain region 112 or the source region 140. In example embodiments, the drain region 112, the source region 140, the channel region 130, and the first pocket region 151 may include group III-V semiconductor materials. For example, the drain region 112, the source region 140, the channel region 130, and the first pocket region 151 may include at least one of the following compounds, indium-gallium-arsenic (InGaAs), indium-gallium-antimony (InGaSb), gallium-antimony (GaSb), indium-arsenic (InAs), gallium-arsenic-antimony (GaAsSb), indium-antimony (InSb), indium-aluminum-antimony (InAlSb), or indium-aluminum-arsenic (InAlAs). In other example embodiments, the channel region 130 may include group IV semiconductor materials, for example, silicon-germanium (SiGe), and the first pocket region 151 may include group IV semiconductor materials, for example, germanium-stannum (GeSn).

In some embodiments, each of the channel region 130 and the first pocket region 151 may include the same materials or different materials. In certain embodiments, if each of the channel region 130 and the first pocket region 151 includes the same materials (e.g., same compounds), for example, InGaAs, at least two elements of InGaAs of the first pocket region 151 has different composition ratios compared to the same at least two elements of InGaAs of the channel region 130.

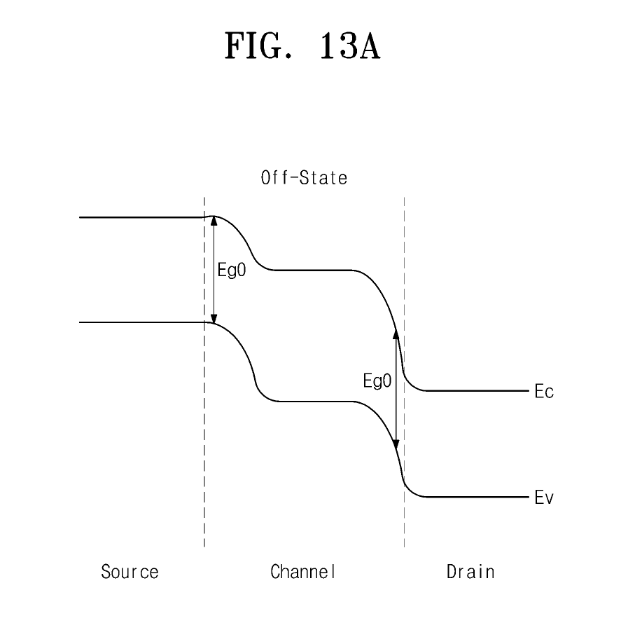

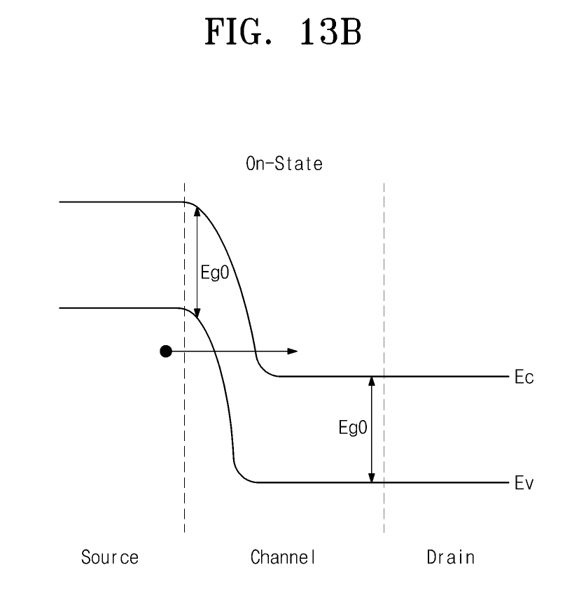

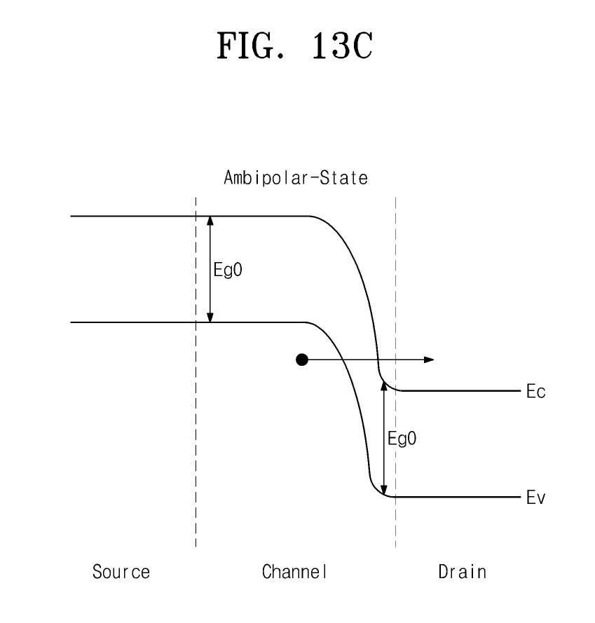

FIGS. 13A, 13B, and 13C are energy band diagrams of a general N-channel tunneling field effect transistor. Unlike a general metal-oxide-semiconductor field effect transistor (MOSFET), a tunneling field effect transistor controls a flow of carriers by a band-to-band tunneling phenomenon, not a thermionic emission phenomenon. For example, if a positive voltage is applied to a gate electrode, the tunneling field effect transistor may be changed from an off-state of FIG. 13A into an on-state of FIG. 13B. As illustrated in FIG. 13B, a carrier may be transferred into a drain by a source-side tunneling phenomenon. This tunneling field effect transistor may have a low sub-threshold swing at room temperature unlike a general MOSFET, and a minimal change of a driving voltage may cause a great change of an output current of the tunneling field effect transistor. However, a general tunneling field effect transistor of which a channel region has a constant energy band gap Eg0 may become in an ambipolar state, as illustrated in FIG. 13C. The ambipolar state means that a drain-side tunnel phenomenon occurs when a negative voltage is applied to the gate electrode. As a result, the general tunneling field effect transistor may have a relatively low on-current and a relatively high off-current.

As illustrated in FIG. 2, in the tunneling field effect transistor according to some embodiments of the inventive concepts, an energy band gap Eg1 of the channel region 130 adjacent to the source region 140 (e.g., the first region R1) may be smaller than an energy band gap Eg2 of the channel region 130 adjacent to the drain 112 (e.g., the second region R2). Thus, a source-side tunneling barrier may be lowered by the relatively small energy band gap Eg1 of the first region R1 adjacent to the source region 140, thereby obtaining a high on-current. In addition, a drain-side tunneling barrier may be increased by the relatively great energy band gap Eg2 of the second region R2 adjacent to the drain region 112, and thus, the ambipolar state (i.e., the drain-side tunneling phenomenon) may be minimized or prevented to obtain a low off-current. This asymmetrical energy band gap may be controlled by composition (ratio) and/or stress of a semiconductor material.

In some embodiments, the drain region 112, the source region 140, and the channel region 130 may include InGaAs, and a gallium (Ga) concentration of the channel region 130 may become lower from the second region R2 to the first region R1 (e.g., in a direction from the drain region to the source region). For example, a ratio of indium (In):gallium (Ga) in the first region R1 may be, for example, 0.7:0.3, and a ratio of In:Ga in the second region R2 may be, for example, 0.53:0.47. As the gallium concentration of the channel region 130 becomes lower from the second region R2 to the first region R1, the energy band gap of the channel region 130 may become smaller gradually or stepwise from the second region R2 to the first region R1. If the energy band gap of the channel region 130 becomes smaller stepwise, the channel region 130 may include a plurality of layers having different composition ratios from each other. In other embodiments, the drain region 112 may include GaSb, the source region 140 may include InGaSb, and the channel region 130 may include InGaSb. In this case, an indium (In) concentration of the channel region 130 may become higher from the second region R2 to the first region R1, and thus, the energy band gap of the channel region 130 may become smaller gradually or stepwise from the second region R2 to the first region R1.

In this case, the first pocket region 151 may include InGaAs, and a ratio of In:Ga of the first pocket region 151 may be, for example, 0.9:0.1.

An energy band gap Eg3 of the first pocket region 151 may be different from the energy band gaps Eg1 and Eg2 of the first and second regions R1 and R2. In some embodiments, the energy band gap Eg3 of the first pocket region 151 may be smaller than the energy band gap Eg1 of the first region R1. The source-side tunneling barrier may be further lowered by the relatively small energy band gap of the first pocket region 151, thereby increasing the on-current of the tunneling field effect transistor. This relatively small energy band gap of the first pocket region 151 may be obtained by compositions, doped states, and/or stress of semiconductor materials included in the first pocket region 151.

In some embodiments, the channel region 130 and the first pocket region 151 may include different compounds (e.g., different sets of elements). In one embodiment, if the channel region 130 includes InGaAs, the first pocket region 151 may include InAs. In this case, a ratio of indium (In):arsenic (As) in the first pocket region 151 may be, for example, 1:1, however, the inventive concepts are not limited thereto. In other embodiments, if the channel region 130 includes InGaSb, the first pocket region 151 may include InSb.

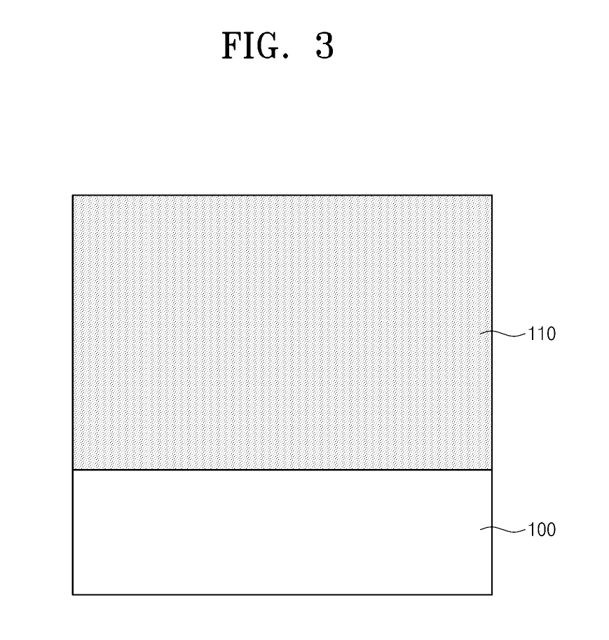

FIGS. 3 to 7 are cross-sectional views illustrating a method of manufacturing a tunneling field effect transistor according to some embodiments of the inventive concepts.

Referring to FIG. 3, a first semiconductor layer 110 may be formed on a substrate 100. The substrate 100 may be, for example, a silicon substrate or a substrate including silicon. The first semiconductor layer 110 may be formed by performing an epitaxial growth process on the substrate 100. In some embodiments, the epitaxial growth process may be a chemical vapor deposition (CVD) process or a molecular beam epitaxy (MBE) process. If a tunneling field effect transistor according to some embodiments is an N-type tunneling field effect transistor, the first semiconductor layer 110 may be doped with N-type dopants (e.g., Si). Alternatively, if the tunneling field effect transistor according to some embodiments is a P-type tunneling field effect transistor, the first semiconductor layer 110 may be doped with P-type dopants (e.g., Zn). In some embodiments, the first semiconductor layer 110 may be doped in-situ or may be doped by an additional ion implantation process performed after a deposition process. In some embodiments, a dopant concentration of the first semiconductor layer 110 may be in a range of, for example, about 1×10¹⁹ atm/cm³ to about 1×10²¹ atm/cm³. The first semiconductor layer 110 may include the same material as that of the drain region 112 described with reference to FIG. 1.

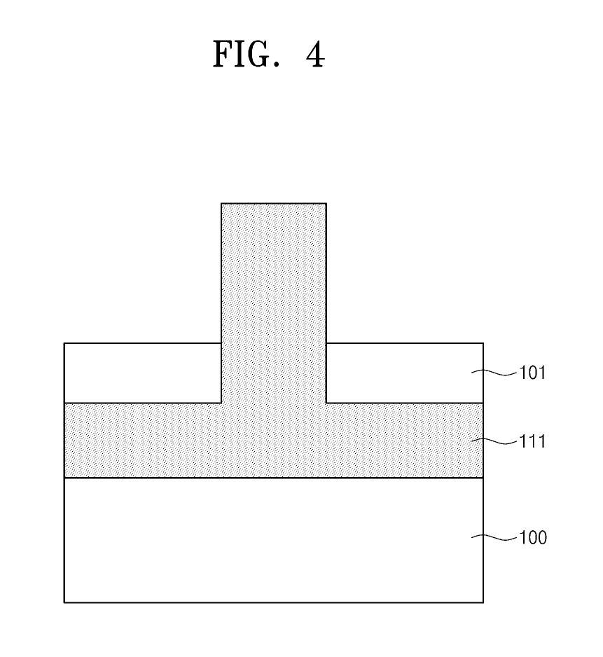

Referring to FIG. 4, the first semiconductor layer 110 may be patterned to form a recess region, and a device isolation layer 101 may be then formed to fill the recess region. As a result, a first semiconductor pattern 111 may be formed. The patterning process of the first semiconductor layer 110 may include a process of forming a mask pattern (not shown) and a dry etching process using the mask pattern. The device isolation layer 101 may be formed of, for example, silicon oxide. The device isolation layer 101 may be formed by a CVD process. The device isolation layer 101 may be recessed to have a top surface lower than a topmost surface of the first semiconductor pattern 111.

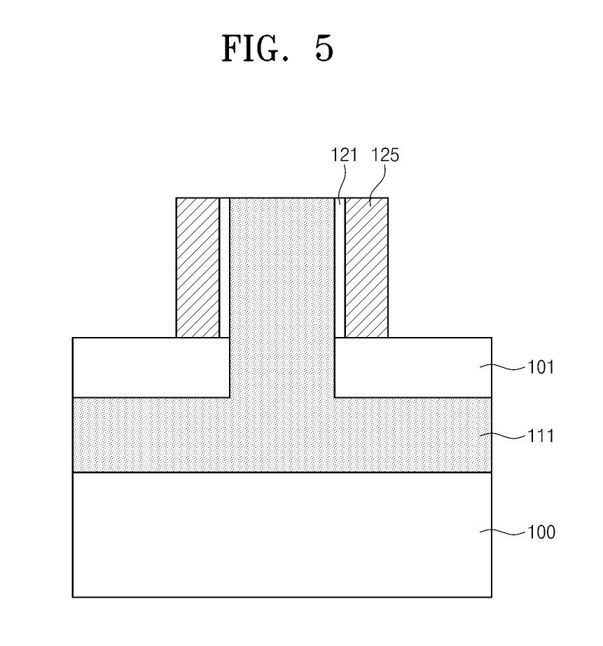

Referring to FIG. 5, a gate dielectric layer 121 and a gate electrode 125 may be sequentially formed on a sidewall of the first semiconductor pattern 111. The gate dielectric layer 121 and the gate electrode 125 may expose the topmost surface of the first semiconductor pattern 111. The gate dielectric layer 121 may be formed of a high-k dielectric material having a dielectric constant higher than that of a silicon oxide layer. For example, the gate dielectric layer 121 may include HfO₂, ZrO₂, or Ta₂O₅. The gate electrode 125 may include a conductive material, for example, a conductive metal nitride (e.g., TiN, TaN, or WN) and/or a metal (e.g., Ti, Ta, or W). A dielectric layer may be formed to cover the first semiconductor pattern 111, and a dry etching process may be then performed on the dielectric layer to form the gate dielectric layer 121. A conductive layer may be formed on the gate dielectric layer 121, and a dry etching process may be then performed on the conductive layer to form the gate electrode 125. In other embodiments, a dielectric layer and a conductive layer may be sequentially formed to cover the first semiconductor pattern 111, and a planarization process and a patterning process may be performed to form the gate dielectric layer 121 and the gate electrode 125.

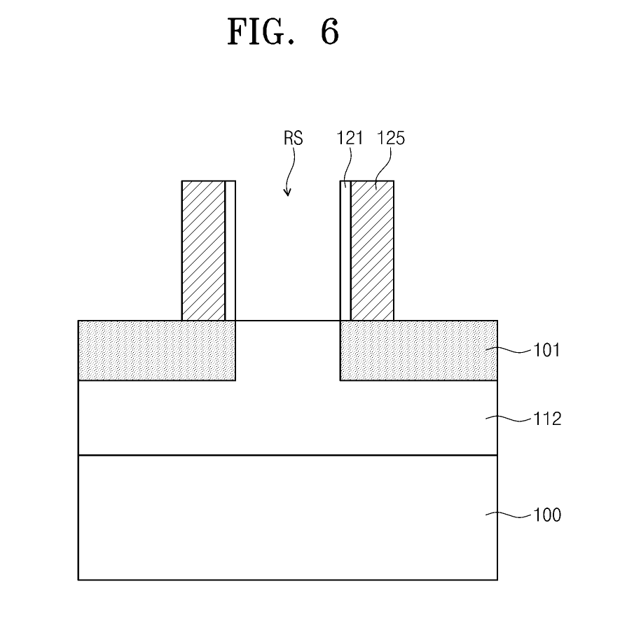

Referring to FIG. 6, an upper portion of the first semiconductor pattern 111 may be selectively removed to form a drain region 112. For example, a top surface of the drain region 112 may be disposed at a substantially same level as a top surface of the device isolation layer 101, as illustrated in FIG. 6, however, the inventive concepts are not limited thereto. By the selective removing process, a recess region RS may be formed. The recess region RS may be defined by the top surface of the drain region 112 and a sidewall of the gate dielectric layer 121.

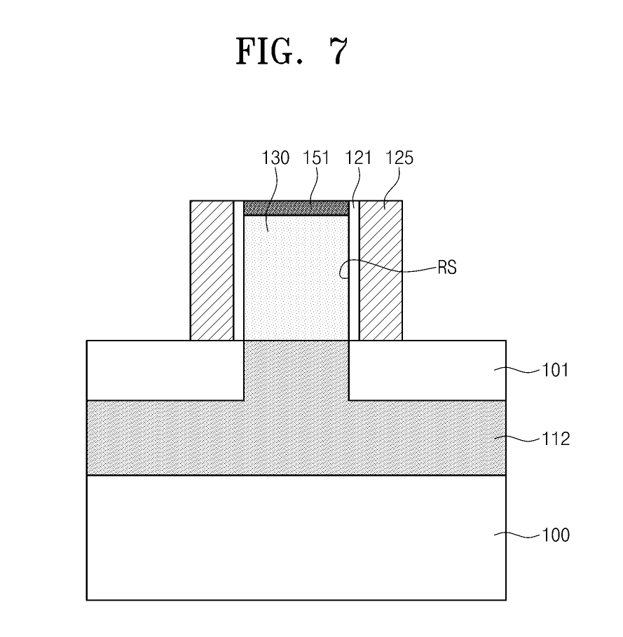

Referring to FIG. 7, a channel region 130 and a first pocket region 151 may be formed to fill the recess region RS. The channel region 130 may be formed by an epitaxial process using the top surface of the drain region 112 exposed by the recess region RS as a seed. The channel region 130 may be an intrinsic semiconductor region (e.g., including only an intrinsic material without any dopant). In other embodiments, the channel region 130 may be a P-type or N-type dopant region (e.g., including the intrinsic material and dopant) which is more lightly doped than the drain region 112.

An upper portion and a lower portion of the channel region 130 may have different composition ratios from each other. In some embodiments, if the channel region 130 includes InGaAs, a gallium (Ga) concentration of the lower portion of the channel region 130 may be higher than a gallium concentration of the upper portion of the channel region 130. In other embodiments, if the channel region 130 includes InGaSb, an indium (In) concentration of the lower portion of the channel region 130 may be lower than an indium concentration of the upper portion of the channel region 130. The different composition ratios of the upper and lower portions of the channel region 130 may be realized by controlling the amounts of sources of the epitaxial process.

The first pocket region 151 may be formed by an epitaxial process using a top surface of the channel region 130 as a seed. For example, a top surface of the first pocket region 151 may be disposed at a substantially same level as a top surface of the gate electrode 125, as illustrated in FIG. 7, however, the inventive concepts are not limited thereto. If the channel region 130 includes InGaAs, the first pocket region 151 may be formed of a material including InAs. In other embodiments, if the channel region 130 includes InGaSb, the first pocket region 151 may be formed of a material including InSb.

Referring again to FIG. 1, a source region 140 may be formed on the first pocket region 151. The source region 140 may be formed by an epitaxial process using a top surface of the first pocket region 151 as a seed. If the tunneling field effect transistor according to some embodiments of the inventive concepts is the N-type tunneling field effect transistor, the source region 140 may be doped with P-type dopants and the drain region 112 may be doped with N-type dopants. Alternatively, if the tunneling field effect transistor according to some embodiments of the inventive concepts is the P-type tunneling field effect transistor, the source region 140 may be doped with N-type dopants and the drain region 112 may be doped with P-type dopants. In some embodiments, the source region 140 may be doped in-situ or may be doped by an additional ion implantation process performed after the epitaxial process. In some embodiments, a dopant concentration of the source region 140 may be in a range of about, for example, 1×10¹⁹ atm/cm³ to about 1×10²¹ atm/cm³.

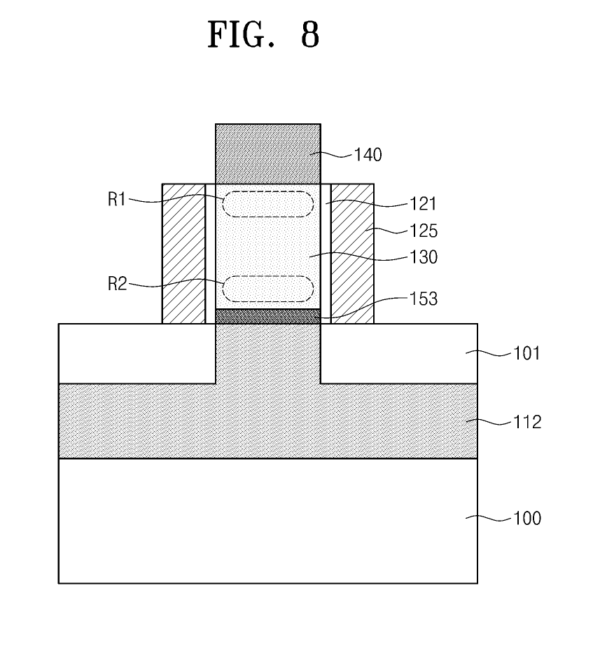

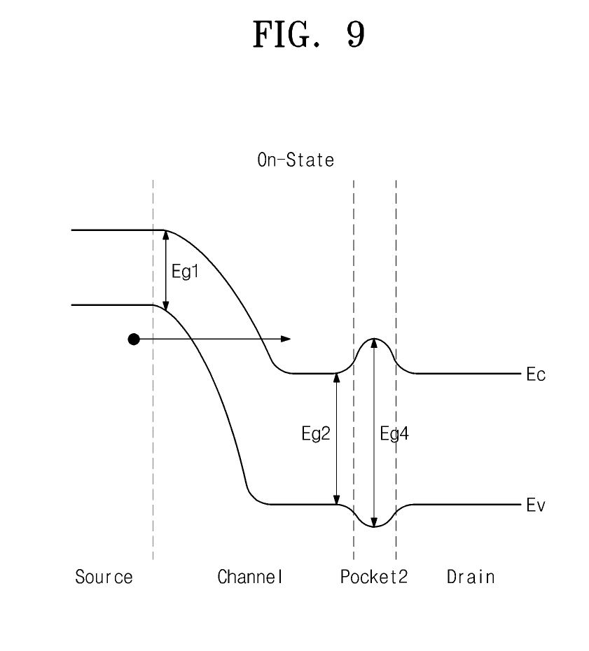

FIG. 8 is a cross-sectional view illustrating a tunneling field effect transistor according to other embodiments of the inventive concepts. FIG. 9 is an energy band diagram of the tunneling field effect transistor of FIG. 8. In the present embodiment, the same descriptions as described in the aforementioned embodiment will be omitted or mentioned briefly for the purpose of ease and convenience in explanation.

Referring to FIGS. 8 and 9, a tunneling field effect transistor according to the present embodiment may include a second pocket region 153 between the channel region 130 and the drain region 112. An energy band gap Eg4 of the second pocket region 153 may be greater than the energy band gap Eg2 of the second region R2 adjacent to the second pocket region 153. The energy band gap Eg2 of the second region R2 may be greater than the energy band gap Eg1 of the first region R1 adjacent to the source region 140.

In one embodiment, a thickness of the second pocket region 153 is less than a thickness of the channel region 130. The thickness of each of the second pocket region 153 and the channel region 130 may be in a direction between the substrate 100 and the source region 140.

A drain-side tunneling barrier may be increased by the second pocket region 153 having the relatively wide energy band gap, and thus, the ambipolar state (i.e., the drain-side tunneling phenomenon) may be minimized or prevented to obtain the low off-current of the tunneling field effect transistor.

In some embodiments, if the channel region 130 includes InGaAs, the second pocket region 153 may include at least one of indium-phosphorus (InP) or indium-aluminum-arsenic (InAlAs). In other embodiments, if the channel region 130 includes InGaSb, the second pocket region 153 may include indium-aluminum-antimony (InAlSb).

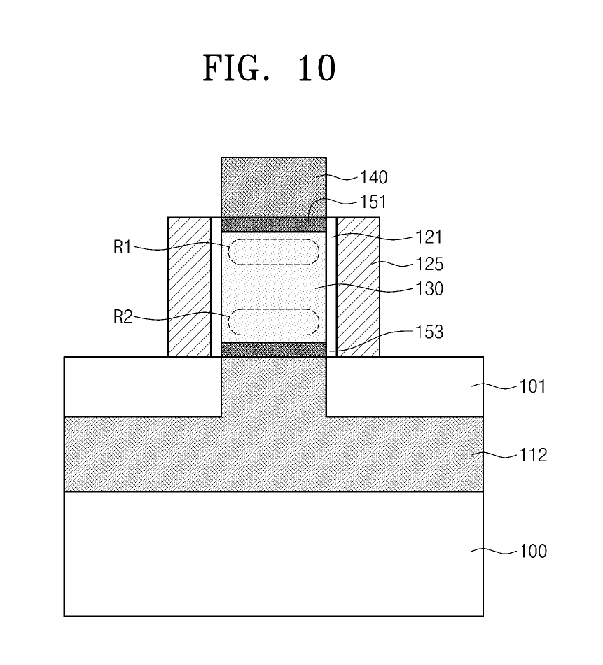

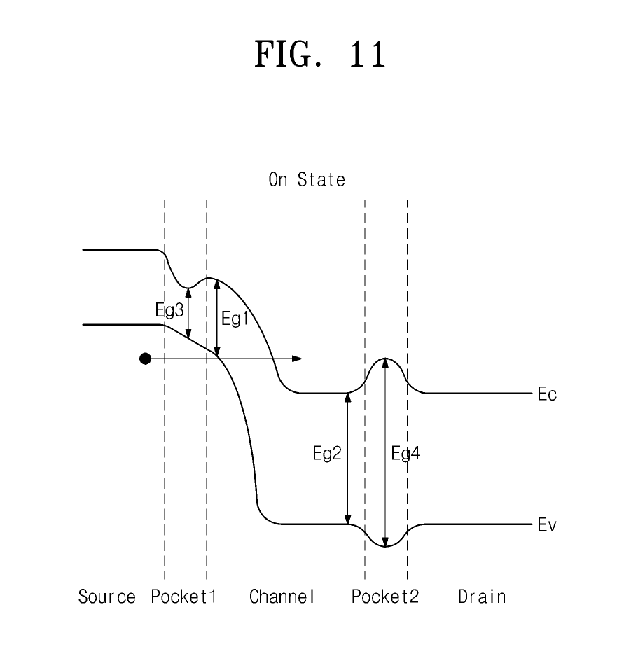

FIG. 10 is a cross-sectional view illustrating a tunneling field effect transistor according to still other embodiments of the inventive concepts. FIG. 11 is an energy band diagram of the tunneling field effect transistor of FIG. 10. In the present embodiment, the same descriptions as described in the aforementioned embodiments will be omitted or mentioned briefly for the purpose of ease and convenience in explanation.

Referring to FIGS. 10 and 11, a tunneling field effect transistor according to the present embodiment may include a first pocket region 151 disposed between the channel region 130 and the source region 140 and a second pocket region 153 disposed between the channel region 130 and the drain region 112. The energy band gap Eg3 of the first pocket region 151 may be smaller than the energy band gap Eg1 of the first region R1 adjacent to the first pocket region 151, and the energy band gap Eg4 of the second pocket region 153 may be greater than the energy band gap Eg2 of the second region R2 adjacent to the second pocket region 153. Also, the energy band gap Eg2 of the second region R2 may be greater than the energy band gap Eg1 of the first region R1 adjacent to the source region 140.

The relatively small energy band gap of the first pocket region 151 may lower a source-side tunneling barrier to obtain the high on-current. In addition, the relatively great energy band gap of the second pocket region 153 adjacent to the drain region 112 may increase a drain-side tunneling barrier, so the ambipolar state (i.e., the drain-side tunneling phenomenon) may be minimized or prevented to obtain the low off-current.

In one embodiment, the thickness of each of the first and second pocket regions 151 and 153 in a direction between the drain 112 and the source 240, is less than a thickness of the channel region 130 in the same direction.

In some embodiments, if the channel region 130 includes InGaAs, the first pocket region 151 may include InAs and the second pocket region 153 may include at least one of InP and InAlAs. In other embodiments, if the channel region 130 includes InGaSb, the first pocket region 151 may include InSb and the second pocket region 153 may include InAlSb.

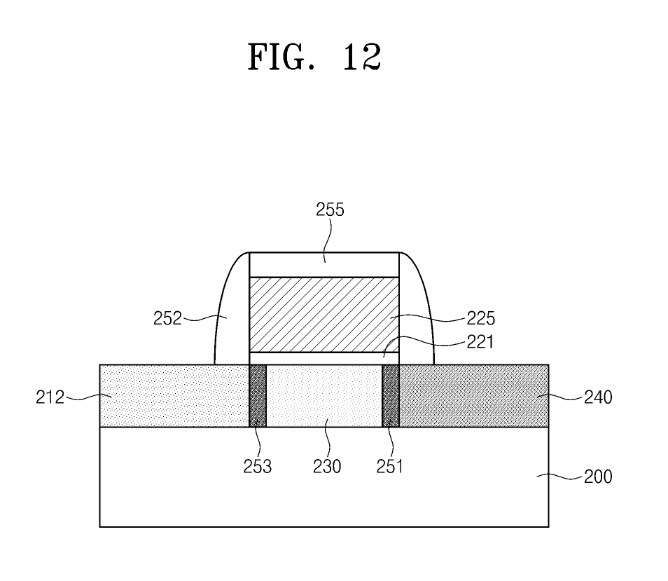

FIG. 12 is a cross-sectional view illustrating a tunneling field effect transistor according to yet other embodiments of the inventive concepts. In the present embodiment, the same descriptions as described in the aforementioned embodiments will be omitted or mentioned briefly for the purpose of ease and convenience in explanation.

Referring to FIG. 12, a drain region 212, a channel region 230, and a source region 240 may be provided on a substrate 200. The channel region 230 may be provided between the drain region 212 and the source region 240. The drain region 212, the channel region 230, and the source region 240 may be disposed at a substantially same level on the substrate 200. The drain region 212, the channel region 230, and the source region 240 may have the same materials, the same conductivity types and the same characteristics as the drain region 112, the channel region 130, and the source region 140 described with reference to FIG. 1. The drain region 212, the channel region 230, and the source region 240 may be formed by epitaxial processes independent of each other and removing processes.

In some embodiments, a first pocket region 251 may be provided between the channel region 230 and the source region 240. The first pocket region 251 may have the same material, the same conductivity type and the same characteristics as the first pocket region 151 described with reference to FIG. 1. In some embodiments, a second pocket region 253 may be provided between the channel region 230 and the drain region 212. The second pocket region 253 may have the same material, the same conductivity type and the same characteristics as the second pocket region 153 described with reference to FIG. 8. In other embodiments, one of the first pocket region 251 and the second pocket region 253 may be omitted.

In one embodiment, the thickness of each of the first and second pocket regions 251 and 253 in a direction between the drain 212 and the source 240, is less than a thickness of the channel region 230 in the same direction.

A gate dielectric layer 221 and a gate electrode 225 may be sequentially stacked on the channel region 230. A spacer 252 may be provided on a sidewall of the gate electrode 225, and a capping layer 255 may be provided on a top surface of the gate electrode 225.

A tunneling field effect transistor according to above disclosed embodiments may be included in a semiconductor device. As used herein, a semiconductor device may refer, for example, to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias (TSVs), or other electrical connection elements, and may include memory devices such as volatile or non-volatile memory devices.

An electronic device, as used herein, may refer to these semiconductor devices, but may additionally include products that include these devices, such as a memory module, a hard drive including additional components, or a mobile phone, laptop, tablet, desktop, camera, or other consumer electronic device, etc.

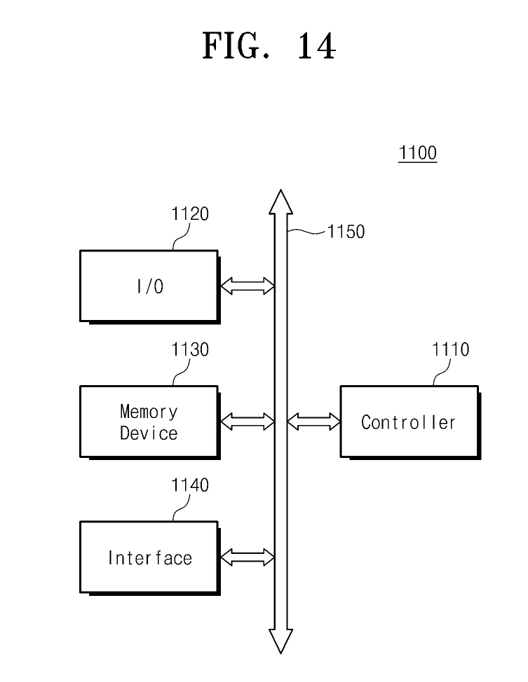

FIG. 14 is a schematic block diagram illustrating an electronic system including a semiconductor device according to certain embodiments of the inventive concepts.

Referring to FIG. 14, an electronic system 1100 according to an embodiment of the inventive concept may include a controller 1110, an input/output (I/O) unit 1120, a memory device 1130, an interface unit 1140, and a data bus 1150. At least two of the controller 1110, the I/O unit 1120, the memory device 1130, and the interface unit 1140 may communicate with each other through the data bus 1150. The data bus 1150 may correspond to a path through which electrical signals are transmitted.

The controller 1110 may include at least one of a microprocessor, a digital signal processor, a microcontroller, or other logic devices having a similar function to any one thereof. The I/O unit 1120 may include, for example, a keypad, a keyboard and/or a display unit. The memory device 1130 may store data and/or commands. The interface unit 1140 may transmit electrical data to a communication network or may receive electrical data from a communication network. The interface unit 1140 may operate by wireless or cable. For example, the interface unit 1140 may include an antenna or a wireless/cable transceiver. Although not shown in the drawings, the electronic system 1100 may further include a fast dynamic random access memory (Fast-DRAM) device and/or a fast static random access memory (Fast-SRAM) device which acts as a working memory for improving an operation of the controller 1110. At least one of the semiconductor devices according to embodiments of the inventive concepts may be provided into the memory device 1130 or may be used as the controller 1110 and/or a portion of the I/O unit 1120.

The electronic system 1100 may be applied to a personal digital assistant (PDA), a portable computer, a web tablet, a wireless phone, a mobile phone, a digital music player, a memory card, or other electronic products. The other electronic products may receive or transmit information data by wireless transmission.

The electronic system 1100 of FIG. 14 may be used as an electronic control device in one of various electronic devices.

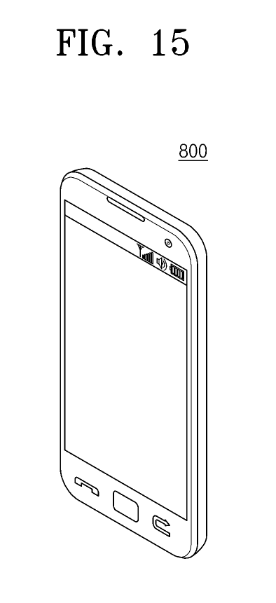

FIG. 15 illustrates an example of a mobile phone 800 applied with the electronic system 1100 of FIG. 14.

In other embodiments, the electronic system 1100 of FIG. 14 may be applied to, for example, a portable notebook, a MP3 player, a navigation device, a solid state disk (SSD), cars, or household appliances.

According to embodiments of the inventive concepts, the tunneling field effect transistor may have the high on-current and the low off-current by the asymmetrical energy band gap of the channel region. In addition, due to the pocket region, the on-current may be further increased and the off-current may be further reduced.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

What is claimed is:

1. A tunneling field effect transistor comprising:
a source region and a drain region;
a channel region including a first material, and disposed between the source region and the drain region; and
a pocket region including a second material different from the first material, and disposed between the source region and the drain region,
wherein the channel region comprises a first region adjacent to the source region, and a second region adjacent to the drain region,
wherein a first energy band gap of the first region is smaller than a second energy band gap of the second region, and
wherein a third energy band gap of the pocket region is different from the first energy band gap and the second energy band gap.

2. The tunneling field effect transistor of claim 1, wherein the pocket region is formed between the source region and the channel region, and
wherein the third energy band gap is smaller than the first energy band gap.

3. The tunneling field effect transistor of claim 2, wherein the first material includes indium-gallium-arsenic (InGaAs), and
wherein the second material includes indium-arsenic (InAs).

4. The tunneling field effect transistor of claim 3, wherein a gallium (Ga) concentration of the first region is lower than a gallium concentration of the second region.

5. The tunneling field effect transistor of claim 2, wherein the first material includes indium-gallium-antimony (InGaSb), and
wherein the second material includes indium-antimony (InSb).

6. The tunneling field effect transistor of claim 5, wherein an indium (In) concentration of the first region is greater than an indium concentration of the second region.

7. The tunneling field effect transistor of claim 1, wherein the pocket region is formed between the drain region and the channel region, and
wherein the third energy band gap is greater than the second energy band gap.

8. The tunneling field effect transistor of claim 7, wherein the first material includes indium-gallium-arsenic (InGaAs), and
wherein the second material includes at least one of indium-phosphorus (InP) and indium-aluminum-arsenic (InAlAs).

9. The tunneling field effect transistor of claim 7, wherein the first material includes indium-gallium-antimony (InGaSb), and
wherein the second material includes indium-aluminum-antimony (InAlSb).

10. The tunneling field effect transistor of claim 1, wherein an energy band gap of the channel region becomes smaller gradually or stepwise from the second region to the first region.

11. The tunneling field effect transistor of claim 1, wherein the source region, the drain region, and the channel region are provided on a substrate, and
wherein the source region and the drain region are spaced apart from each other in a direction substantially perpendicular to a top surface of the substrate.

12. The tunneling field effect transistor of claim 11, further comprising:
a gate dielectric layer and a gate electrode stacked on each other on a sidewall of the channel region; and
a device isolation layer disposed at both sides of the channel region when viewed from a plan view,
wherein the gate dielectric layer and the gate electrode are in contact with a top surface of the device isolation layer.

13. The tunneling field effect transistor of claim 1, wherein the pocket region is a first pocket region, further comprising:
a second pocket region between the source region and the drain region,
wherein the first pocket region is formed between the source region and the channel region,
wherein the second pocket region is formed between the drain region and the channel region,
wherein the third energy band gap is smaller than the first energy band gap, and
wherein a fourth energy band gap of the second pocket region is greater than the second energy band gap.

14. A semiconductor device comprising:
a substrate; and
one or more tunneling field effect transistors,
wherein at least one of the one or more tunneling field effect transistors includes:
a source structure and a drain structure on the substrate;
a channel layer including a first compound including a first intrinsic material, and disposed between the source structure and the drain structure; and
a first layer including a second compound including a second intrinsic material different from the first intrinsic material, and disposed between the source structure and the drain structure,
wherein a concentration of one element of the first compound varies in a direction from the source region to the drain region.

15. The semiconductor device of claim 14, wherein the channel layer includes a first set of energy band gaps, each energy band gap being smaller in a direction from the drain structure to the source structure, and
wherein the first layer includes a second energy band gap different from each of the first set of energy band gaps.

16. The semiconductor device of claim 15, wherein the second energy band gap is smaller than each of the first set of energy band gaps when the first layer is located between the source structure and the channel layer, and
wherein the second energy band gap is greater than each of the first set of energy band gaps when the first layer is located between the drain structure and the channel layer.

17. The semiconductor device of claim 16, wherein:
when the first layer is located between the source structure and the channel layer,
a second layer is located between the drain structure and the channel layer, and includes a third energy band gap greater than each of the first set of energy band gaps; and
when the first layer is located between the drain structure and the channel layer,
a third layer is located between the source structure and the channel layer, and includes a third energy band gap smaller than each of the first set of energy band gaps.

18. A semiconductor device including one or more tunneling field effect transistors, wherein at least a first tunneling field effect transistor comprises:
a substrate;
a source structure and a drain structure on the substrate;
a channel layer including a first area adjacent to the source structure, and a second area adjacent to the drain structure, the channel layer formed between the source structure and the drain structure;
a first layer contacting a first surface of the channel layer;
a gate electrode; and
a gate dielectric layer including a first surface contacting the gate electrode, and a second surface contacting the channel layer,
wherein the channel layer includes a first compound and the first layer includes a second compound different from the first compound, and
wherein a thickness of the channel layer is greater than a thickness of the first layer.

19. The semiconductor device of claim 18, wherein the first area has a first energy band gap, the second area has a second energy band gap greater than the first energy band gap, and the first layer has a third energy band gap different from the first energy band gap and the second energy band gap, wherein:
either a second surface of the first layer opposite to the first surface of the first layer contacts the source structure, and the third energy band gap is smaller than the first energy band gap and the second energy band gap,
or the second surface of the first layer contacts the drain structure, and the third energy band gap is greater than the first energy band gap and the second energy band gap.

20. The semiconductor device of claim 18, wherein the first tunneling field effect transistor further comprises:
a second layer contacting a second surface of the channel layer opposite to the first surface of the channel layer, and including a third compound different from the first compound,
wherein a thickness of the channel layer is greater than a thickness of the second layer.
